(19) United States
(12) Patent Application Publication
(10) Pub. No.: US 2024/0419079 A1
(43) Pub. Date: Dec. 19, 2024

(54) CHEMICALLY SELECTIVE ADHESION AND STRENGTH PROMOTERS IN SEMICONDUCTOR PATTERNING

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/705,427

(22) PCT Filed: Oct. 25, 2022
(86) PCT No.: PCT/US2022/047667

§ 371 Date: Apr. 26, 2024

Related U.S. Application Data
(60) Provisional application No. 63/271,873, filed on Oct. 26, 2021.

(51) Int. Cl. G03F 7/16; G03F 7/00; H01L 21/311

(52) U.S. Cl. CPC G03F 7/168; G03F 7/70033; H01L 21/31144

(57) ABSTRACT

A method of patterning a substrate includes depositing an underlayer on the substrate, coating the underlayer with a solubility-shifting agent, layering a photoresist on the substrate, such that the photoresist covers the solubility-shifting agent and diffusing the solubility-shifting agent a predetermined distance into the photoresist to provide a solubility-shifted region of the photoresist, wherein the solubility-shifted region forms a footer layer in a bottom portion of the photoresist. Then, the method includes exposing the photoresist to a pattern of actinic radiation, developing the photoresist to form a relief pattern over the footer layer, wherein the relief pattern comprises structures separated by gaps, and etching the substrate to remove portions of the footer layer under the gaps, such that uniform structures are provided.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a photoresist, to a pattern of actinic radiation and subsequently developing the photoresist to form a relief pattern. The relief pattern then acts as an etch mask, which, when one or more etching processes are applied to the substrate, cover portions of the substrate that are not to be etched.

In semiconductor patterning, lithographic exposure is desirably consistent throughout a feature in order to promote etch resistance and local mechanical strength. In extreme ultraviolet (EUV) patterning, the absorption of photons within the photoresist is sufficiently high as to result in significantly less exposure of the bottom of the photoresist than the top. This leads to lower strength and greater variation in etch resistance through the photoresist. In other words, the photoresist experiences a top-down gradient of exposure to the EUV patterning. For example, a top portion of an EUV photoresist tends to receive more photons than a bottom portion, and thus, may become more insoluble to a given developer. This tends to result in a narrowing of features or undercutting of the pattern, as the bottom portion of the EUV photoresist is only partially soluble in the given developer. Thus, to improve pattern fidelity and regularity, particularly for multi patterning use cases, improvements to local pattern strength are needed.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of patterning a substrate that includes depositing an underlayer on the substrate, coating the underlayer with a solubility-shifting agent, layering a photoresist on the substrate, such that the photoresist covers the solubility-shifting agent and diffusing the solubility-shifting agent a predetermined distance into the photoresist to provide a solubility-shifted region of the photoresist, wherein the solubility-shifted region forms a footer layer in a bottom portion of the photoresist. Then, the method includes exposing the photoresist to a pattern of actinic radiation, developing the photoresist to form a relief pattern over the footer layer, wherein the relief pattern comprises structures separated by gaps, and etching the substrate to remove portions of the footer layer under the gaps, such that uniform structures are provided.

In another aspect, embodiments disclosed herein relate to a method of patterning a substrate that includes depositing an underlayer on the substrate, coating the underlayer with a solubility-shifting agent, layering a photoresist on the substrate, such that the photoresist covers the solubility-shifting agent, and exposing the photoresist to a pattern of actinic radiation. Then, the method includes diffusing the solubility-shifting agent a predetermined distance into the photoresist to provide a solubility-shifted region of the photoresist, wherein the solubility-shifted region forms a footer layer in a bottom portion of the photoresist, developing the photoresist to form a relief pattern over the footer layer, wherein the relief pattern comprises structures separated by gaps, and etching the substrate to remove the portions of the footer layer that are under the gaps, such that uniform structures are provided.

In yet another aspect, embodiments disclosed herein relate to a method of patterning a substrate including depositing an underlayer on the substrate, wherein the underlayer comprises a secondary electron emitter, layering a photoresist on the substrate, such that the photoresist covers the underlayer, exposing the photoresist to a pattern of actinic radiation, wherein the secondary electron emitter layer improves exposure of a bottom portion of the photoresist to provide a footer layer that has a different polarity than a top portion of the photoresist, developing the photoresist to form a relief pattern over the footer layer, wherein the relief pattern comprises structures separated by gaps, and etching the substrate to remove portions of the footer layer under the gaps, such that uniform structures are provided.

Other aspects and advantages of the claimed subject matter will be apparent from the following description and the appended claims.

### BRIEF DESCRIPTION OF DRAWINGS

FIG. 1 is a block-flow diagram of a method in accordance with one or more embodiments of the present disclosure.

FIGS. 2A-F are schematic illustrations of coated substrates at respective points of a method in accordance with one or more embodiments of the present disclosure.

FIG. 3 is a block-flow diagram of a method in accordance with one or more embodiments of the present disclosure.

### DETAILED DESCRIPTION

The present disclosure generally relates to a method of patterning a semiconductor substrate. Herein, the terms “semiconductor substrate” and “substrate” are used interchangeably, and may be any semiconductor material including, but not limited to, semiconductor wafers, semiconductor material layers, and combinations thereof. The method may include treating a bottom portion of a photoresist to improve patterning regularity on a substrate. In one or more embodiments, the adhesion and strength of the photoresist are improved locally by increasing an amount of polymerization enhancing chemistry in a portion of the photoresist. The method may be particularly useful in EUV lithography.

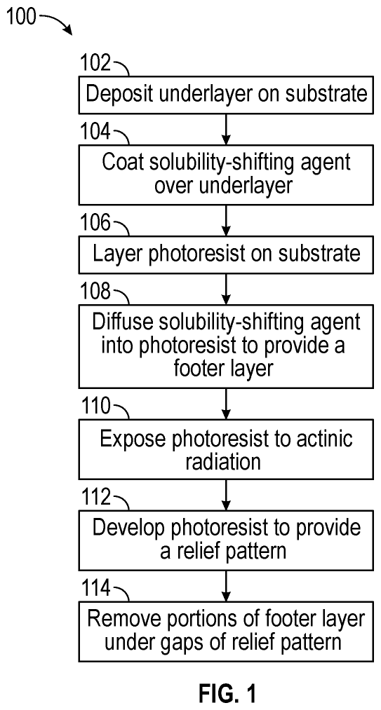

As described above, in one aspect, the present disclosure relates to a method for improving photoresist pattern regularity in lithography processes. A method, 100, in accordance with the present disclosure is shown in, and discussed with reference to, FIG. 1. Initially, in method 100, at block 102 an underlayer is deposited on a substrate. Then, at block 104, a solubility-shifting agent may be coated over the underlayer, and, at block 106, a photoresist is layered over the solubility-shifting agent. Next, method 100 includes, at block 108, diffusing the solubility-shifting agent into a bottom portion of the photoresist. Diffusion of the solubility-shifting agent into a bottom portion of the photoresist may provide a footer layer that has a different solubility than the top portion of the photoresist. After the solubility-shifting agent is diffused into the bottom portion of the photoresist to provide a footer layer, at block 110, the photoresist may be exposed to a pattern of actinic radiation, baked, and then, at block 112, developed. Development of the photoresist may provide a relief pattern of photoresist over the footer layer that includes structures separated by gaps. As such, some portions of the footer layer may be under the structures and other portions of the footer layer may be under the gaps. Method 100 then includes, at block 114, removing the portions of the footer layer that are under the gaps and between the structures of the photoresist to provide a pattern of photoresist having a physically stable footer layer with no undercutting.

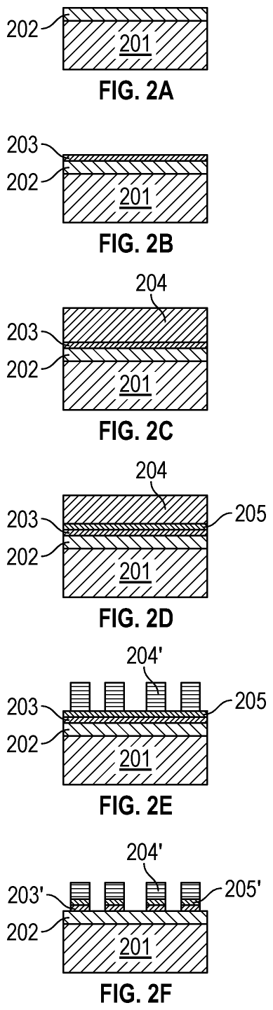

Schematic depictions of a coated substrate at various points during the method described above are shown in FIGS. 2A, 2B, 2C, 2D, 2E and 2F. Herein “a coated substrate” refers to a substrate that is coated with one or more layers, such as a first photoresist layer and a second resist layer. FIG. 2A shows a substrate including an underlayer. FIG. 2B shows a substrate that includes an underlayer coated with a solubility-shifting agent. In FIG. 2C, a photoresist is layered over the solubility-shifting agent. FIG. 2D shows a coated substrate after the solubility-shifting agent has been diffused into the photoresist, such that a footer layer is provided. In FIG. 2E, the photoresist has been developed to provide a relief pattern of photoresist over the footer layer that comprises structures separated by gaps. Finally, FIG. 2F shows a coated substrate that has been directionally etched to remove portions of the footers that are under the gaps of the relief pattern.

As described above, at block 102, the method initially includes depositing an underlayer on a substrate. FIG. 2A shows an example of an underlayer 202 on a substrate 201. In one or more embodiments, the underlayer is a bottom anti reflection coating (BARC). A bottom antireflective coating may be desirable where the substrate and/or underlying layers would otherwise reflect a significant amount of incident radiation during photoresist exposure such that the quality of the formed pattern would be adversely affected. Such coatings can improve depth-of-focus, exposure latitude, linewidth uniformity and CD control. Antireflective coatings are typically used where the resist is exposed to deep ultraviolet radiation (300 nm or less), for example, KrF (248 nm), ArF (193 nm) or EUV (13.5 nm) radiation. The antireflective coating can comprise a single layer or a plurality of different layers. Suitable antireflective materials and methods of formation are known in the art. Antireflective materials are commercially available, for example, those sold under the AR™ tradename by DuPont (Wilmington, Del. USA), such as AR™ 3, AR™ 40A and AR™ 124 antireflectant materials.

In one or more embodiments, the underlayer comprises an existing adhesion layer and a separate layer. The existing adhesion layer may be a coating such as, for example, a silane, in order to modify the surface energy of the substrate. Suitable silanes include, but are not limited to hexamethyldisilizane (HMDS).

Then, at block 104, method 100 includes coating a solubility-shifting agent over the underlayer. A coated substrate in accordance with block 104 is shown in FIG. 2B. When the underlayer is a separate layer an adhesion layer may be disposed between underlayer 202 and solubility-shifting agent 203 (not shown). The solubility-shifting agent 203 is shown as a thin coating over the underlayer 202. The thickness of the solubility-shifting agent coating is not particularly limited and may be altered based on the desired line cut width. The solubility-shifting agent may be a material that is absorbed into the underlayer via a bake, and in some instances herein may be referred to as an “absorbed material.” The process of absorbing the solubility-shifting agent into the underlayer is described in detailed below.

The composition of the solubility-shifting agent may depend on the tone of the photoresist to be layered over it at block 106 of method 100. Generally, the solubility-shifting agent may be any chemical that activates with light or heat. For example, when the photoresist is a negative tone developed (NTD) photoresist, the solubility-shifting agent may include an acid or thermal acid generator. The acid or generated acid in the case of a TAG should be sufficient with heat to cause cleavage of the bonds of acid-decomposable groups of the polymer in a surface region of the first photoresist pattern to cause increased solubility of the first photoresist polymer in a specific developer to be applied. The acid or TAG is typically present in the composition in an amount of from about 0.01 to 20 wt % based on the total solids of the solubility-shifting agent.

Preferable acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Exemplary aromatic acids that are free of fluorine include wherein aromatic acids of the general formula (I):

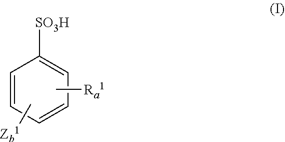

wherein: R1 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z1 independently represents a group chosen from carboxyl, hydroxy, nitro, cyano, C1 to C5 alkoxy, formyl and sulfonic acid; a and b are independently an integer from 0 to 5; and a+b is 5 or less.

Exemplary aromatic acids may be of the general formula (II):

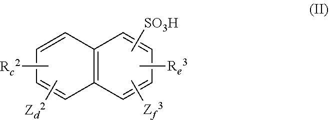

wherein: R2 and R3 each independently represents a substituted or unsubstituted C1-C20 alkyl group, a substituted or unsubstituted C5-C16 aryl group or a combination thereof, optionally containing one or more group chosen from carbonyl, carbonyloxy, sulfonamido, ether, thioether, a substituted or unsubstituted alkylene group, or a combination thereof; Z2 and Z3 each independently represents a group chosen from carboxyl, hydroxy, nitro, cyano, C1 to C5 alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility-shifting agent include those the general formula (III) or (IV):

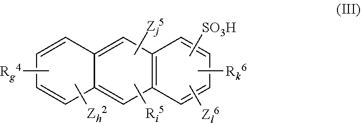

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 2; i+j is 2 or less; k and l are independently an integer from 0 to 3; and k+l is 3 or less;

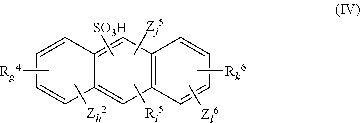

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 1; i+j is 1 or less; k and l are independently an integer from 0 to 4; and k+l is 4 or less.

Suitable aromatic acids may alternatively be of the general formula (V):

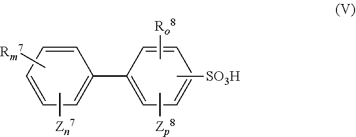

wherein: R7 and R8 each independently represents a substituted or unsubstituted C1-C20 alkyl group, a substituted or unsubstituted C5-C14 aryl group or a combination thereof, optionally containing one or more group chosen from carboxyl, carbonyl, carbonyloxy, sulfonamido, ether, thioether, a substituted or unsubstituted alkylene group, or a combination thereof; Z7 and Z8 each independently represents a group chosen from hydroxy, nitro, cyano, C1 to C5 alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may have the general formula (VI):

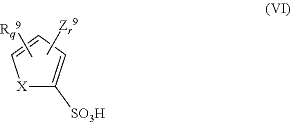

wherein: X is O or S; R9 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z9 independently represents a group chosen from carboxyl, hydroxy, nitro, cyano, C1 to C5 alkoxy, formyl and sulfonic acid; q and r are independently an integer from 0 to 3; and q+r is 3 or less.

In one or more embodiments, the acid is a free acid having fluorine substitution. Suitable free acids having fluorine substitution may be aromatic or nonaromatic. For example, free acid having fluorine substitution that may be used as solubility-shifting agent include, but are not limited to the following:

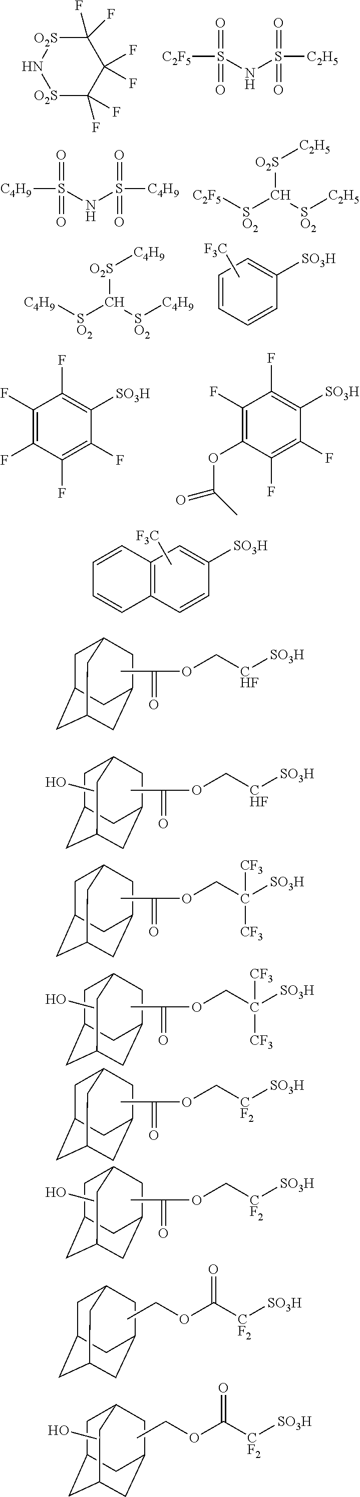

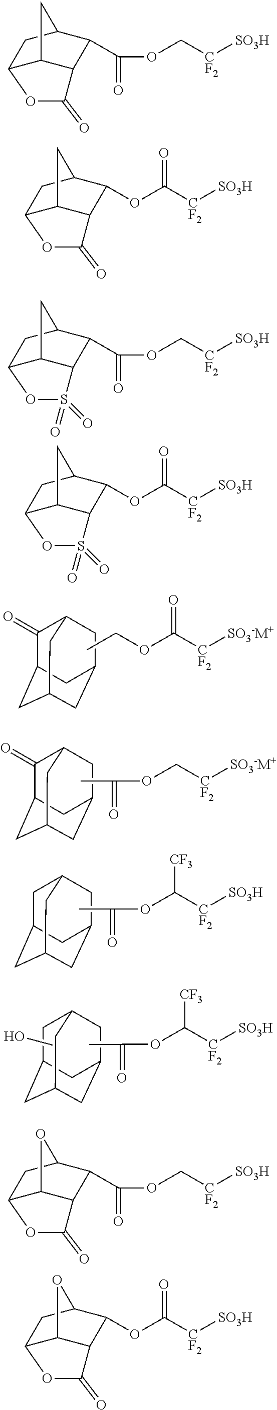

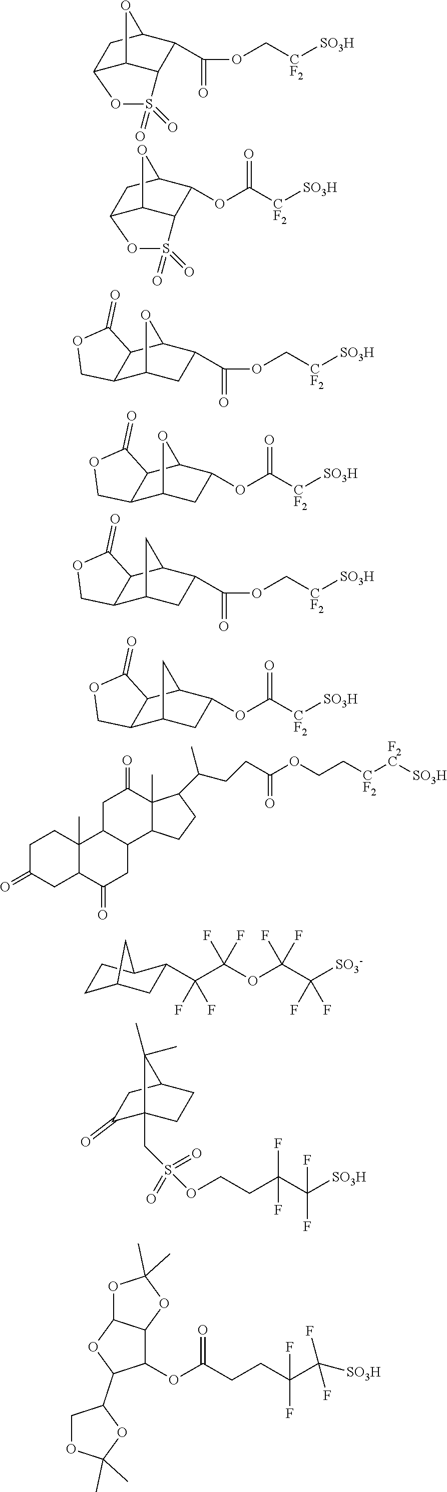

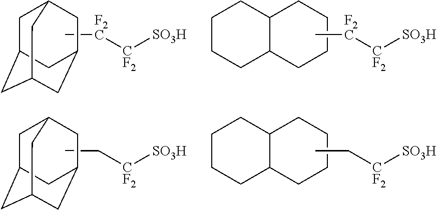

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

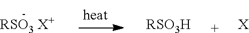

wherein RSO₃⁻ is the TAG anion and X⁺ is the TAG cation, preferably an organic cation. The cation can be a nitrogen-containing cation of the general formula (I):

(BH)⁺ (I)

which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)⁺ include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

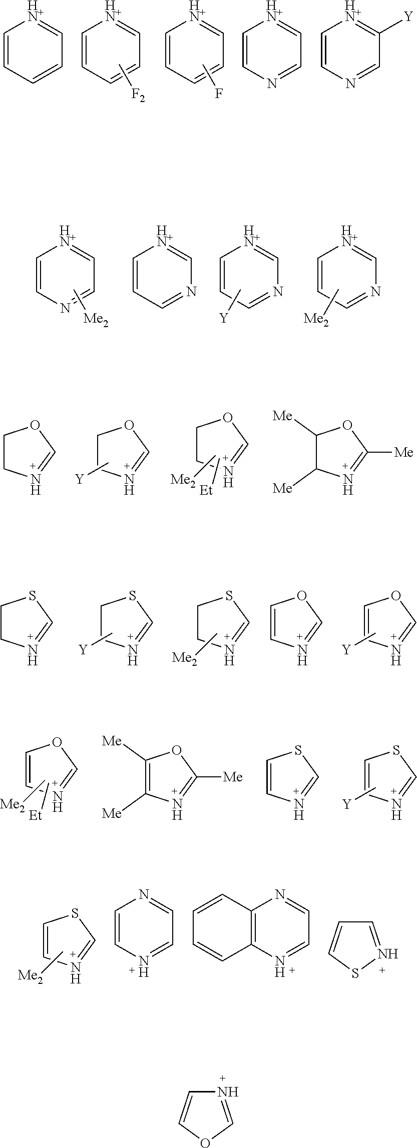

in which Y is alkyl, preferably, methyl or ethyl.

In particular embodiments, the solubility-shifting agent may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; an acid generator such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof.

Alternatively, when the photoresist is a positive tone developed (PTD) photoresist, the solubility-shifting agent may include a base or base generator. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups each having 1 to about 8 carbon atoms, and preferably 1 to about 5 carbon atoms such as hydroxymethyl, hydroxyethyl and hydroxybutyl groups. Specific examples of hydroxyamines include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quarternary ammonium salt, nifedipine, carbamate, and combinations thereof. Exemplary thermal base generators include o-{(.beta.-(dimethylamino)ethyl)aminocarbonyl}benzoic acid, o-{(.gamma.-(dimethylamino)propyl)aminocarbonyl}benzoic acid, 2,5-bis{(.beta.-(dimethylamino)ethyl)aminocarbonyl}terephthalic acid, 2,5-bis{(.gamma.-(dimethylamino)propyl)aminocarbonyl}terephthalic acid, 2,4-bis{(.beta.-(dimethylamino)ethyl)aminocarbonyl}isophthalic acid, 2,4-bis{(.gamma.-(dimethylamino)ethyl)aminocarbonyl}isophthalic acid, and combinations thereof.

In one or more embodiments, the solubility-shifting agent includes a solvent. The solvent may be any suitable solvent that may facilitate with coating the solubility-shifting agent over the underlayer. Accordingly, the solvent may be miscible with, or able to dissolve or suspend, other components included in the solubility-shifting agent, such as, for example, an acid, acid generator, base or base generator. The solvent is typically chosen from water, organic solvents and mixtures thereof. In some embodiments, the solvent may include an organic-based solvent system comprising one or more organic solvents. The term “organic-based” means that the solvent system includes greater than 50 wt % organic solvent based on total solvents of the solubility-shifting agent composition, more typically greater than 90 wt %, greater than 95 wt %, greater than 99 wt % or 100 wt % organic solvents, based on total solvents of the solubility-shifting agent compositions. The solvent component is typically present in an amount of from 90 to 99 wt % based on the solubility-shifting agent composition.

Suitable organic solvents for the solubility-shifting agent composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C₄-C₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C₅-C₉ fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents.

In one or more embodiments, the solvent preferably comprises one or more polar organic solvents. For example, the solubility-shifting agent may include a polar solvent such as methyl isobutyl carbinol (MIBC). The solubility-shifting agent may also include aliphatic hydrocarbons, esters, and ethers as cosolvents such as, for example, decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in amount ranging from 1 to 40%, based on the total volume of solvent.

Alternatively, in one or more embodiments, the solvent preferably comprises one or more non-polar organic solvents. The term “non-polar organic-based” means that the solvent system includes greater than 50 wt % of combined non-polar organic solvents based on total solvents of the solubility-shifting agent composition, more typically greater than 70 wt %, greater than 85 wt % or 100 wt %, combined non-polar organic solvents, based on total solvents of the solubility-shifting agent composition. The non-polar organic solvents are typically present in the solvent in a combined amount of from 70 to 98 wt %, preferably 80 to 95 wt %, more preferably from 85 to 98 wt %, based on the total solvent.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent includes one or more alcohol and/or ester solvents. For certain compositions, an alcohol and/or ester solvent may provide enhanced solubility with respect to the solid components of the composition. Suitable alcohol solvents include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C₅₋₉ fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C₄₋₉ monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent are typically present in a combined amount of from 2 to 50 wt %, more typically in an amount of from 2 to 30 wt %, based on the total amount of solvent.

The solvent may also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the total amount of solvent.

As described above, the solubility-shifting agent is coated over the underlayer. To properly coat the underlayer, the solubility-shifting agent may include a matrix polymer. Any matrix polymer commonly used in the art may be included in the solubility-shifting material. The matrix polymer should have good solubility in the solvent included in the solubility-shifting agent. The matrix polymer can be formed from one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof.

In some embodiments, the polymer contains one or more functional groups chosen, for example, from hydroxy, acid groups such as carboxyl, sulfonic acid and sulfonamide, silanol, fluoroalcohol such as hexafluoroisopropyl alcohol [—C(CF₃)₂OH], anhydrates, lactones, esters, ethers, allylamine, pyrrolidones and combinations thereof. The polymer can be a homopolymer or a copolymer having a plurality of distinct repeat units, for example, two, three, four or more distinct repeat units. In one aspect, the repeat units of the polymer are all formed from (meth)acrylate monomers, are all formed from (vinyl)aromatic monomers or are all formed from (meth)acrylate monomers and (vinyl)aromatic monomers. When the polymer includes more than one type of repeat unit, it typically takes the form of a random copolymer.

The solubility-shifting agent typically includes a single polymer but may optionally include one or more additional polymers. The content of the polymer in the solubility-shifting agent will depend, for example, on the target thickness of the layer, with a higher polymer content being used when a thicker layer is desired. The polymer is typically present in the solubility-shifting agent composition in an amount of from 80 to 99.9 wt %, more typically from 90 to 99 wt %, or 95 to 99 wt %, based on total solids of the solubility-shifting agent composition. The weight average molecular weight (Mw) of the polymer is typically less than 400,000, preferably from 3000 to 50,000, more preferably from 3000 to 25,000, as measured by GPC versus polystyrene standards. Typically, the polymer will have a polydispersity index (PDI=Mw/Mn) of 3 or less, preferably 2 or less, as measured by GPC versus polystyrene standards.

Suitable polymers for use in the solubility-shifting agent compositions are commercially available and/or can readily be made by persons skilled in the art. For example, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

Solubility-shifting agents including a matrix polymer may be coated over the underlayer according to methods known in the art. Typically, a solubility-shifting agent that includes a matrix polymer may coated over the first relief pattern by spin coating. The solids content of the solubility-agent may be tailored to provide a film of a desired thickness of the solubility-shifting agent over the first relief pattern. For example, the solids content of the solubility-shifting agent solution may be adjusted to provide a desired film thickness based upon the specific coating equipment utilized, the viscosity of the solution, the speed of the coating tool and the amount of time allowed for spinning. A typical thickness of the solubility-shifting agent may range from about 200 Å to about 1500 Å.

In one or more embodiments, a solubility-shifting agent includes an active material (i.e., an acid, acid generator, base, or base generator), a solvent, and a matrix polymer as previously described. A typical formulation for such solubility-shifting agent may include about 1 to 10 wt % solids and 90 to 99 wt % solvent, based on the total weight of the solubility shifting agent, where the solids include the active material and the matrix polymer. Within the solids content, the active material may be included in an amount ranging from about 1 to about 5 wt %.

The solubility-shifting agent may include additives having various purposes, depending on the particular chemistry being used. In some embodiments, a surfactant may be included in the solubility-shifting agent. A surfactant may be included in the solubility-shifting agent to help with coating quality, especially when needing to fill thin gaps between features of the first photoresist. Any suitable surfactant known in the art may be included in the solubility-shifting agent.

As noted above, in one or more embodiments, the solubility-shifting agent is absorbed into the underlayer. Absorption of the solubility-shifting agent into the underlayer may be achieved by performing a thermal pretreatment such as a bake. The bake may be a soft bake. The temperature and time of the soft bake may depend on the identity of the first resist, and the desired amount of diffusion of the solubility-shifting agent into the first resist. Typically, a soft bake may be performed for about 30 seconds to about 90 seconds at a temperature ranging from about 50 to about 150° C.

After absorption into the underlayer, a coating layer that includes little to no active solubility-shifting material may remain on the first resist. In one or more embodiments, the coating layer may be removed by a rinse. The rinse may be accomplished by rinsing the coated substrate with a solvent that dissolves the coating layer but does not dissolve the underlayer. The rinse may be carried out using any suitable method, for example, by dipping a substrate in a bath filled with the solvent for a fixed time (dip method), by raising the solvent on a substrate surface by the effect of a surface tension and keeping it still for a fixed time, thereby dissolving the coating layer (puddle method), by spraying the solvent on a substrate surface (spray method), or by continuously ejecting the solvent on a substrate rotating at a constant speed while scanning the solvent ejecting nozzle at a constant rate (dynamic dispense method).

At block 106 of method 100, a photoresist is layered on the substrate. A coated substrate layered with an underlayer 202, a solubility-shifting agent 203, and a photoresist 204 is shown in FIG. 2C. The photoresist may be layered on the substrate such that it coats the underlayer and the solubility-shifting agent completely. The photoresist may be deposited on the substrate according to any suitable method known in the art such as, for example, spin-on deposition or vapor-phase treatment.

Generally, a photoresist is a chemically amplified photosensitive composition that comprises a polymer, a photoacid generator, and a solvent. In particular embodiments, the photoresist is an EUV resist, where the term EUV resist denotes a resist sensitive to EUV light. The photoresist may include a polymer. Suitable polymers may be any standard polymer typically used in photoresist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the-OH group of p-hydroxystyrene may be protected with a tert-butyloxycarbonyl protecting group. Such protecting group may alter the reactivity and solubility of the polymer included in the first photoresist. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The polymer may include an acid-labile group which, on decomposition, forms a carboxylic acid on the polymer is preferably a tertiary ester group of the formula —C(O)OC(R¹)₃ or an acetal group of the formula —C(O)OC(R²)₂OR³, wherein: R¹ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R¹ optionally including as part of its structure one or more groups chosen from —O—, —C(O)—, —C(O)—O—, or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer included in the photoresist.

The polymer may further include, as polymerized, a monomer comprising an acid-labile group, the decomposition of which group forms an alcohol group or a fluoroalcohol group on the polymer. Suitable such groups include, for example, an acetal group of the formula —COC(R²)₂OR³—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

In one or more embodiments, the photoresist includes a photoacid generator. The photoacid generator may be a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The photoresist may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above.

In one or more embodiments, the photoresist is an EUV resist, where the term EUV resist denotes a resist sensitive to EUV light. Suitable EUV resists may be a chemically amplified resist, a metal organic resist, and a dry resist. Chemically amplified EUV resists may include a polymer and a photoacid generator as described above.

In one or more embodiments, the EUV resist is a metal organic resist. Thus, in one or more embodiments, the photoresist is a metalorganic or metal-based resist based on metal oxide chemistry, including metal oxo/hydroxo compositions that utilize radiation sensitive ligands to enable patterning with actinic radiation. One class of radiation-based resists use peroxo ligands as the radiation sensitive stabilization ligands. Peroxo based metal oxo-hydroxo compounds are described, for example, in U.S. Pat. No. 9,176,377B2 to Stowers et al., entitled “Patterned Inorganic Layers, Radiation Based Patterning Compositions and Corresponding Methods,” incorporated herein by reference. Related resist compounds are discussed in published U.S. patent application 2013/0224652A1 to Bass et al., entitled “Metal Peroxo Compounds With Organic Co-ligands for Electron Beam, Deep UV and Extreme UV Resist Applications,” incorporated herein by reference. An effective type of resists have been developed with alkyl ligands as described in U.S. Pat. No. 9,310,684B2 to Meyers et al., entitled “Organometallic Solution Based High Resolution Patterning Compositions,” published U.S. patent application 2016/0116839A1 to Meyers et al., entitled “Organometallic Solution Based High Resolution Patterning Compositions and Corresponding Methods,” and U.S. patent application Ser. No. 15/291,738 entitled “Organotin Oxide Hydroxide Patterning Compositions, Precursors, and Patterning”, all of which are incorporated herein by reference. Tin compositions are exemplified in these documents, and the data presented herein focuses on tin-based resists, although the Edge bead removal solutions described herein are expected to be effective for other metal-based resists described below.

With respect to the tin-based photoresists of particular interest, these photoresists are based on the chemistry of organometallic compositions represented by the formula RzSnO(2-(z/2)-(x/2))(OH)x where 0<z≤2 and 0<(z+x)≤4, in which R is a hydrocarbyl group with 1-31 carbon atoms. However, it has been found that at least some of the oxo/hydroxo ligands can be formed following deposition based on in situ hydrolysis based on compositions represented by the formula RnSnX4-n where n=1 or 2, in which X is a ligand with a hydrolysable M-X bond. In general, suitable hydrolysable ligands (X in RSnX3) may include alkynides RC≡C, alkoxides RO—, azides N3-, carboxylates RCOO—, halides and dialkylamides. Thus, in some embodiments all or a portion for the oxo-hydroxo compositions can be substituted with the Sn—X compositions or a mixture thereof. The R—Sn bonds generally are radiation sensitive and form the basis for the radiation processable aspect of the resist. But some of the RzSnO(2-(z/2)-(x/2))(OH)x composition can be substituted with MO((m/2)-1/2)(OH)x where 0<z≤2, 0<(z+w)≤4, m=formal valence of Mm+, 0≤l≤m, y/z=(0.05 to 0.6), and M=M′ or Sn, where M′ is a non-tin metal of groups 2-16 of the periodic table, and R is hydrocarbyl groups with 1-31 carbon atoms. Thus, the photoresist being processed during the edge bead rinse can comprise a selected blend of RzSnO(2-(z/2)-(x/2))(OH)x, R′nSnX4-n, and/or MO((m/2)-1/2)(OH)x, in which generally a significant fraction of the composition includes alkyl-tin bonds. Other photoresist compositions include, for example, compositions having metal carboxylate bonds (e.g., ligands of acetate, propanoate, butanoate, benzoate, and/or the like), such as dibutyltin diacetate.

While metal oxo/hydroxo or carboxylate-based photoresists referenced above are particularly desirable, some other high-performance photoresists may be suitable in some embodiments. Specifically, other metal-based photoresists include those with high etch selectivity to substrate and hardmask materials. These may include photoresists such as metal-oxide nanoparticle resists (e.g., Jiang, Jing; Chakrabarty, Souvik; Yu, Mufei; et al., “Metal Oxide Nanoparticle Resists for EUV Patterning”, Journal Of Photopolymer Science And Technology 27(5), 663-666 2014, incorporated herein by reference), or other metal containing resists (A Platinum-Fullerene Complex for Patterning Metal Containing Nanostructures, D. X. Yang, A. Frommhold, D. S. He, Z. Y. Li, R. E. Palmer, M. A. Lebedeva, T. W. Chamberlain, A. N. Khlobystov, A. P. G. Robinson, Proc SPIE Advanced Lithography, 2014, incorporated herein by reference). Other metal-based resists are described in published U.S. patent application 2009/0155546A1 to Yamashita et al., entitled “Film-Forming Composition, Method for Pattern Formation, and Three-Dimensional Mold,” and U.S. Pat. No. 6,566,276 to Maloney et al., entitled “Method of Making Electronic Materials,” both of which are incorporated herein by reference.

In other embodiments, the photoresist is an EUV-sensitive film applied by a vapor deposition process, known as a “dry resist”. The film may be formed by mixing a vapor stream of an organometallic precursor with a vapor stream of a counter-reactant so as to form a polymerized organometallic material. The hardmask may also be formed by depositing the organometallic polymer-like material onto the surface of the semiconductor substrate. The mixing and depositing operations may be performed by chemical vapor deposition (CVD), atomic layer deposition (ALD), and ALD with a CVD component, such as a discontinuous, ALD-like process in which metal precursors and counter-reactants are separated in either time or space.

Such EUV-sensitive films comprise materials which, upon exposure to EUV, undergo changes, such as the loss of bulky pendant substituents bonded to metal atoms in low density M-OH rich materials, allowing their crosslinking to denser M-O-M bonded metal oxide materials. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a hydrophobic surface and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density and cross-linking of the film. Removal may be by wet processing or dry processing.

The thin films are, in various embodiments, organometallic materials, comprising SnOx or other metal oxides moieties. The organometallic compounds may be made in a vapor phase reaction of an organometallic precursor with a counter reactant. In various embodiments, the organometallic compounds are formed through mixing specific combinations of organometallic precursors having bulky alkyl groups or fluoroalkyl with counter-reactants and polymerizing the mixture in the vapor phase to produce a low-density, EUV-sensitive material that deposit onto the substrate.

In various embodiments, organometallic precursors comprise at least one alkyl group on each metal atom that can survive the vapor-phase reaction, while other ligands or ions coordinated to the metal atom can be replaced by the counter-reactants. Organometallic precursors include those of the formula:

MaRbLc (Formula 1)

wherein: M is a metal with a high EUV absorption cross-section; R is alkyl, such as CnH2n+1, preferably wherein n≥3; L is a ligand, ion or other moiety which is reactive with the counter reactant; a≥1; b≥1; and c≥1.

In various embodiments, M has an atomic absorption cross section equal to or greater than 1×107 cm2/mol. M may be, for example, selected from the group consisting of tin, bismuth, antimony and combinations thereof. In some embodiments, M is tin. R may be fluorinated, e.g., having the formula CnFxH(2n+1). In various embodiments, R has at least one beta-hydrogen or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof. L may be any moiety readily displaced by a counter-reactant to generate an M-OH moiety, such as a moiety selected from the group consisting of amines (such as dialkylamino, monalkylamino), alkoxy, carboxylates, halogens, and mixtures thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris) dimethylamino tin, n-propyl tris(diethylamino) tin, and analogous alkyl(tris)(t-butoxy) tin compounds such as t-butyl tris(t-butoxy) tin. In some embodiments, the organometallic precursors are partially fluorinated.

Counter-reactants preferably have the ability to replace the reactive moieties ligands or ions (e.g., L in Formula 1, above) so as to link at least two metal atoms via chemical bonding. Counter-reactants can include water, peroxides (e.g., hydrogen peroxide), di- or polyhydroxy alcohols, fluorinated di- or polyhydroxy alcohols, fluorinated glycols, and other sources of hydroxyl moieties. In various embodiments, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges.

The thin films may include optional materials in addition to an organometallic precursor and counter-reactants to modify the chemical or physical properties of the film, such as to modify the sensitivity of the film to EUV or enhancing etch resistance. Such optional materials may be introduced, such as by doping during vapor phase formation prior to deposition on the substrate, after deposition of the film, or both. In some embodiments, a gentle remote H2 plasma may be introduced so as to replace some Sn-L bonds with Sn—H, which can increase reactivity of the resist under EUV.

In various embodiments, the EUV-patternable films are made and deposited on the substrate using vapor deposition equipment and processes among those known in the art. In such processes, the polymerized organometallic material is formed in vapor phase or in situ on the surface of the substrate. Suitable processes include, for example, chemical vapor deposition (CVD), atomic layer deposition (ALD), and ALD with a CVD component, such as a discontinuous, ALD-like process in which metal precursors and counter-reactants are separated in either time or space.

In general, methods comprise mixing a vapor stream of an organometallic precursor with a vapor stream of a counter-reactant so as to form a polymerized organometallic material and depositing the organometallic material onto the surface of the semiconductor substrate. As will be understood by one of ordinary skill in the art, the mixing and depositing aspects of the process may be concurrent, in a substantially continuous process.

In an exemplary continuous CVD process, two or more gas streams, in separate inlet paths, of organometallic precursor and source of counter-reactant are introduced to the deposition chamber of a CVD apparatus, where they mix and react in the gas phase, to form agglomerated polymeric materials (e.g., via metal-oxygen-metal bond formation). The streams may be introduced, for example, using separate injection inlets or a dual-plenum showerhead. The apparatus is configured so that the streams of organometallic precursor and counter-reactant are mixed in the chamber, allowing the organometallic precursor and counter-reactant to react to form a polymerized organometallic material. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups prevents the formation of densely packed network and produces porous, low density films.

The CVD process is generally conducted at reduced pressures, such as from 10 milliTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature.

The thickness of the EUV-patternable film formed on the surface of the substrate may vary according to the surface characteristics, materials used, and processing conditions. In various embodiments, the film thickness may range from 0.5 nm to 100 nm and is preferably of sufficient thickness to absorb most of the EUV light under the conditions of EUV patterning. For example, the overall absorption of the resist film may be 30% or less (e.g., 10% or less, or 5% or less) so that the resist material at the bottom of the resist film is sufficiently exposed. In some embodiments, the film thickness is from 10 to 20 nm. Without limiting the mechanism, function, or utility of present technology, it is believed that, unlike wet, spin-coating processes of the art, the processes of the present technology have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

After layering the photoresist on the substrate, method 100 includes diffusing the solubility-shifting agent into the photoresist at block 108. Diffusion of the solubility-shifting agent into the photoresist may provide a layer of polarity switched resist. In one or more embodiments, diffusion of the solubility-shifting agent into the photoresist is achieved by performing a bake. The bake may be carried out with a hotplate or oven. The temperature and time of the bake may depend on the composition of the photoresist, and the desired amount of diffusion of the solubility-shifting agent into the photoresist. Suitable conditions for the bake may include a temperature ranging from 50 to 160° C., and a time ranging from about 30 to 90 seconds. In one or more embodiments, after the bake, a solubility-shifted region, i.e., a layer of polarity switched resist, may be present in a bottom portion of the photoresist. The solubility-shifted region of the first photoresist may be referred to herein as a “footer layer.” The amount of diffusion of the solubility-shifting agent may correspond to the thickness of the footer layer. In some embodiments, the footer layer extends into the second resist such that it has a thickness of about 1 to about 60 nm. For example, the thickness of the footer layer may range from a lower limit of one of 1, 5, 10, 15, 20, and 25 nm to an upper limit of one of 40, 45, 50, 55, and 60 nm, where any lower limit may be paired with any mathematically compatible upper limit.

As described above, diffusion of the solubility-shifting agent may provide a footer layer in a bottom portion of the photoresist. A coated substrate including a footer layer is shown in FIG. 2D. As shown in FIG. 2D, the coated substrate includes a substrate 201 and an underlayer 202. The underlayer 202 is coated with a solubility-shifting agent 203. The photoresist 204 is coated over the solubility-shifting agent and the substrate. A footer layer 205 is shown in a bottom portion of the photoresist 204.

The footer layer may have a different solubility than the region of the photoresist that was unexposed to the solubility-shifting agent, i.e., a top portion of the photoresist. As such, the footer layer and the unexposed region of the photoresist may be soluble in different developers.

At block 112 of method 100, the photoresist is exposed to a pattern of actinic radiation. The photoresist may be exposed to actinic radiation using a KrF excimer laser at 248 nm, ArF excimer laser at 193 nm, or an extreme ultraviolet (EUV) exposure tool at 13.5 nm. In particular embodiments, the photoresist is exposed to an EUV exposure tool at 13.5 nm.

In order to impart a shape, or relief pattern, in the photoresist, a mask may be used to block a portion of the photoresist from the actinic radiation. After the actinic radiation is applied, the unexposed portion of the resist may have a different solubility than the exposed portion of the resist. As such, subsequent development of the photoresist, shown at block 114 of method 100, such as rinsing with a photoresist developer will dissolve either the unexposed portion or the exposed portion. Notably, in one or more embodiments, the footer layer in the bottom portion of the photoresist will not dissolve in the photoresist developer. FIG. 2E shows a substrate after the photoresist has been exposed to a pattern of actinic radiation and developed with a photoresist developer. As shown in FIG. 2E, a relief pattern includes structures 204′ made of the photoresist that are separated by gaps. At the base of the structures, the footer layer 205 remains.

As described above, development of the photoresist after exposure to a pattern of actinic radiation will dissolve either the unexposed portion or the exposed portion. A relief pattern provided when the unexposed portion of the resist remains after rinsing with a developer is a positive tone developed resist. In contrast, a relief pattern provided when the exposed portion of the resist remains after rinsing with a developer is either a negative resist or a negative tone developed resist.

In some embodiments, the photoresist is a positive tone developed (PTD) resist. In such embodiments, the relief pattern may include a polymer made from the above-described monomers, wherein any monomers including a reactive functional group are protected. As such, a PTD photoresist may be organic soluble, and thus the relief pattern may be provided by rinsing with a photoresist developer that is basic. Suitable basic photoresist developers include quaternary ammonium hydroxides, such as tetramethylammonium hydroxide (TMAH).

In other embodiments, the photoresist is a negative resist. In such embodiments, the first relief pattern may include a polymer made from the above-described monomers, wherein any monomers including a reactive functional group are not protected. Exposure to actinic radiation results in crosslinking of the polymer in areas of exposure, rendering the polymer insoluble to developers. The unexposed, and thus uncrosslinked, areas may then be removed using an appropriate developer to form the relief pattern.

In yet other embodiments, the photoresist is a negative tone developed (NTD) photoresist. Similar to PTD photoresists, NTD photoresists may include a polymer made from the above-described monomers, wherein any monomers including a reactive functional group are protected. As such, a NTD photoresist may be organic soluble, but instead of developing the exposed areas with a photoresist developer that is basic, the relief pattern may be provided by rinsing the photoresist with a photoresist developer including an organic solvent. Suitable organic solvents that may be used as a first resist developer include n-butyl acetate (NBA) and 2-heptanone.

As noted above, and shown in FIG. 2E, the relief pattern is provided over the footer layer and includes structures of the photoresist separated by gaps. In one or more embodiments, the presence of the footer layer provides structures that have a structurally strong base. For example, the presence of the footer layer may limit or prevent undercutting of the photoresist that is commonly caused during development.

Finally, at block 114, method 100 includes removing portions of the footer layer that are under the gaps of the relief pattern. The portion of the footer layer under the gaps of the relief pattern may be removed by methods known in the art, such as, for example, a plasma dry etch process. In one embodiment, the etch process can be an anisotropic etch process such as reactive ion etching. In some embodiments where the organic material is a pure hydrocarbon-based material, the etchant can be a dry etchant, such as O₂ or halide-based plasma. In one or more embodiments, the solubility-shifting agent coating may remain over the underlayer. In such embodiments, the remaining solubility-shifting agent coating is removed along with the portions of the footer layer that are under the gaps of the relief pattern. As such, an etched photoresist including uniform structures may be provided. For example, FIG. 2F shows a coated substrate that includes structures of an etched photoresist 204′ provided over a footer layer 205′, a layer of the solubility-shifting agent 203′ and an underlayer 202 on a substrate 201. In embodiments in which the solubility-shifting agent is absorbed into the underlayer, there is no layer of solubility shifting agent at this point in the method. An etched photoresist prepared according to method 100 may provide uniform structures that have a structurally strong base with no undercutting.

Method 100 represents one possible embodiment and is not intended to limit the scope of the present invention. As will be appreciated by one of ordinary skill in the art, the present invention may encompass various alternative methods, such as, for example, methods in which the photoresist is exposed to a pattern of actinic radiation before the solubility-shifting agent is diffused into the photoresist. In such alternate embodiments, the components and techniques used in the methods may be as previously described with reference to method 100.

In one or more embodiments, the actinic radiation is applied to the photoresist before diffusion of the solubility-shifting agent. In such embodiments, a method may include initially depositing an underlayer on a substrate, and then coating the underlayer with a solubility-shifting agent. A photoresist may then be layered onto the substrate, such that is covers the solubility-shifting agent. At this point, the photoresist may be exposed to a pattern of actinic radiation, such as, for example, using an EUV exposure tool. Then, the solubility-shifting agent may be diffused into the photoresist a predetermined distance to provide a footer layer composed of a solubility-shifted photoresist. After the solubility-shifting agent is diffused into the photoresist, the substrate may be developed and etched as described with reference to method 100, to provide a relief pattern including uniform structures of the photoresist with no undercutting.

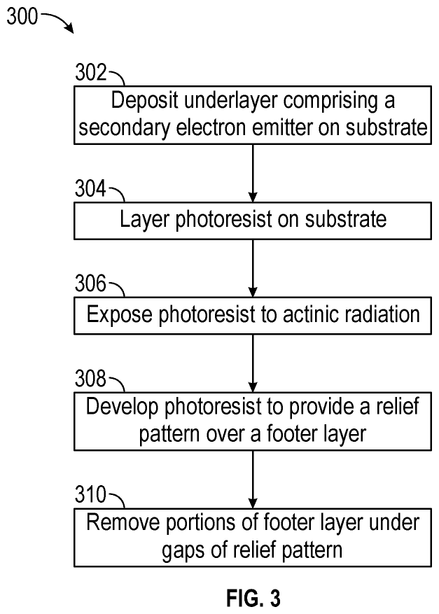

Alternatively, in one or more embodiments, a non-amplified chemical resist is the photoresist and strong secondary electron emitter is the underlayer. Secondary electron emission is a method of electron emission from the surface, typically of a metal or metal oxide. When actinic radiation is injected into the metal oxide, secondary electrons are emitted from the surface. This phenomenon can be used to create the desired effect of a footer or adhesion layer at the interface of the resist and the substrate. A method in accordance with such embodiments is shown in, and discussed with reference to, FIG. 3. As shown, method 100 initially includes depositing an underlayer on a substrate at block 302. The substrate is as previously described. The underlayer may be a secondary electron emitter layer. Suitable secondary electron emitted underlayers include, but are not limited to, magnesium oxide, beryllium oxide, and a combination thereof. In some embodiments, the second electron emitter layer is co-deposited with a strong absorber, such as, for example, tin oxide (SnO). In some embodiments, the underlayer includes multiple secondary electron emitter layers.

Then, method 300 includes layering a photoresist on the substrate at block 304. In one or more embodiments, the photoresist is an EUV resist. Suitable EUV resists include metal organic resists and dry resists as previously described with respect to method 100. Additionally, in some embodiments, the photoresist includes other additive, such as the additives described above with respect to method 100.

After layering the photoresist on the substrate, method 300 includes exposing the photoresist to a pattern of actinic radiation at block 306. In one or more embodiments, the pattern of actinic radiation has a wavelength in the EUV spectrum, such as, for example, 13.5 nm.

Due to the presence of the secondary electron emitter layer, the photoresist may experience additional chemical exposure near the surface, i.e., an area at the interface between the secondary electron emitter layer and the photoresist layer may become polarity switched, or crosslinked, depending on the tone of the resist. Unlike conventional adhesion techniques, this process is based on improving the exposure of a bottom portion of the photoresist. Accordingly, the secondary electron emitter layer, in improving the exposure of the bottom portion of the photoresist to the pattern of actinic radiation, provides a “footer layer” in the photoresist. This leads to lower line edge roughness and allows direct patterning on resist.

As described above, in order to impart a shape, or relief pattern, in the photoresist, a mask may be used to block a portion of the photoresist from the actinic radiation. After the actinic radiation is applied, the unexposed portion of the resist may have a different solubility than the exposed portion of the resist. As such, subsequent development of the photoresist, shown at block 308 of method 300, such as rinsing with a photoresist developer will dissolve either the unexposed portion or the exposed portion. Notably, in one or more embodiments, the footer layer in the bottom portion of the photoresist will not dissolve in the photoresist developer. In one or more embodiments, the presence of the footer layer provides structures that have a structurally strong base. For example, the presence of the footer layer may limit or prevent undercutting of the photoresist that is commonly caused during development.

Finally, at block 310, method 300 includes removing portions of the footer layer that are under the gaps of the relief pattern. Removal of the footer layer may be carried out as previously described with respect to method 100. An etched photoresist prepared according to method 300 may provide uniform structures that have a structurally strong base with no undercutting.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

1. A method of patterning a substrate comprising:
depositing an underlayer on the substrate;
coating the underlayer with a solubility-shifting agent;
layering a photoresist on the substrate, such that the photoresist covers the solubility-shifting agent;
diffusing the solubility-shifting agent a predetermined distance into the photoresist to provide a solubility-shifted region of the photoresist, wherein the solubility-shifted region forms a footer layer in a bottom portion of the photoresist;
exposing the photoresist to a pattern of actinic radiation;
developing the photoresist to form a relief pattern over the footer layer, wherein the relief pattern comprises structures separated by gaps; and
etching the substrate to remove portions of the footer layer under the gaps, such that uniform structures are provided.

2. A method of patterning a substrate comprising:
depositing an underlayer on the substrate;
coating the underlayer with a solubility-shifting agent;
layering a photoresist on the substrate, such that the photoresist covers the solubility-shifting agent;
exposing the photoresist to a pattern of actinic radiation;
diffusing the solubility-shifting agent a predetermined distance into the photoresist to provide a solubility-shifted region of the photoresist, wherein the solubility-shifted region forms a footer layer in a bottom portion of the photoresist;
developing the photoresist to form a relief pattern over the footer layer, wherein the relief pattern comprises structures separated by gaps; and
etching the substrate to remove the portions of the footer layer that are under the gaps, such that uniform structures are provided.

3. The method of claim 1, wherein the underlayer is a bottom anti reflective coating (BARC) layer.

4. The method of claim 1, wherein the solubility-shifting agent comprises an acid generator.

5. The method of claim 4, wherein the acid generator is free of fluorine.

6. The method of claim 4, wherein the acid generator is selected from the group consisting of pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, triphenylsulfonium antimonate, and combinations thereof.

7. The method of claim 1, wherein the solubility-shifting agent comprises an acid.

8. The method of claim 7, wherein the acid is free of fluorine.

9. The method of claim 7, wherein the acid is selected from the group consisting of trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, and combinations thereof.

10. The method of claim 1, wherein the solubility-shifting agent comprises a base.

11. The method of claim 1, wherein the solubility-shifting agent comprises a base generator.

12. The method of claim 1, wherein the solubility-shifting agent comprises a matrix polymer comprising monomers with ethylenically unsaturated polymerizable double bonds, wherein the monomers are selected from the group consisting of (meth)acrylate monomers, (meth)acrylic acids, vinyl aromatic monomers, such as-styrene, hydroxystyrene, vinyl naphthalene, acenaphthylene, vinyl alcohol, vinyl chloride, vinyl pyrrolidone, vinyl pyridine, vinyl amine, vinyl acetal, maleic anhydride, maleimides, norbornenes, and combinations thereof.

13. The method of claim 1, wherein the solubility-shifting agent comprises a matrix polymer comprising monomers comprising one or more functional groups selected from the group consisting of hydroxy, carboxyl, sulfonic acid, sulfonamide, silanol, fluoroalcohol, anhydrates, lactones, esters, ethers, allylamine, pyrrolidones, and combinations thereof.

14. The method of claim 1, further comprising, directly after coating the underlayer with the solubility-shifting agent, diffusing the solubility-shifting agent into the underlayer.

15. The method of claim 14, wherein diffusing the solubility-shifting agent into the underlayer is achieved by performing a bake.

16. The method of claim 1, wherein the photoresist is an EUV resist.

17. The method of claim 1, wherein the footer layer comprises a solubility-shifted region of the photoresist.

18. The method of claim 1, further comprising, after removing the portions of the footer layer that are under the gaps, removing the solubility-shifting agent that remains on the underlayer.

19. The method of claim 1, further comprising, after coating the underlayer with a solubility-shifting agent:
diffusing the solubility-shifting agent into the underlayer; and
rinsing to remove residual solubility-shifting agent.

20. A method of patterning a substrate comprising:
depositing an underlayer on the substrate, wherein the underlayer comprises a secondary electron emitter;
layering a photoresist on the substrate, such that the photoresist covers the underlayer;
exposing the photoresist to a pattern of actinic radiation, wherein the secondary electron emitter layer improves exposure of a bottom portion of the photoresist to provide a footer layer that has a different polarity than a top portion of the photoresist;
developing the photoresist to form a relief pattern over the footer layer, wherein the relief pattern comprises structures separated by gaps; and
etching the substrate to remove portions of the footer layer under the gaps, such that uniform structures are provided.

21. The method of claim 20, wherein the secondary electron emitter is selected from the group consisting of magnesium oxide, beryllium oxide, and a combination thereof.

22. The method of claim 20, wherein the photoresist is an EUV resist.
